(19) United States
(12) Patent Application Publication
(10) Pub. No.: US 2026/0308753 A1
(43) Pub. Date: Oct. 8, 2026

(54) FLUORINE-CONTAINING AMORPHOUS CARBON FILM AND METHOD FOR PRODUCING SAME

(71) Applicant: KEIO UNIVERSITY, Tokyo (JP)

(72) Inventors: Tetsuya SUZUKI, Kanagawa (JP); Akira SHIRAKURA, Tokyo (JP)

(21) Appl. No.: 19/482,067

(22) PCT Filed: Mar. 6, 2024
(86) PCT No.: PCT/JP2024/008463

§ 371 Date: Nov. 6, 2025

(30) Foreign Application Priority Data
May 8, 2023 (JP) 2023-076611

(51) Int. Cl. C23C 16/28; C23C 16/455; C23C 16/505

(52) U.S. Cl. CPC C23C 16/28; C23C 16/45512; C23C 16/505

(57) ABSTRACT

A fluorine-containing amorphous carbon film is a monolayer film formed of carbon, fluorine, and oxygen. An average fluorine content percentage in a film thickness direction of the monolayer film is 30 atomic % or greater and 40 atomic % or less, an average oxygen content percentage in the film thickness direction is 5 atomic % or greater and 20 atomic % or less, and a remainder is a carbon atom.

### TECHNICAL FIELD

The present invention relates to a fluorine-containing amorphous carbon film and a method for producing the fluorine-containing amorphous carbon film. More specifically, the present invention relates to a fluorine-containing amorphous carbon film that realizes a hard coating having a low refractive index and good water repellency and a method for producing the fluorine-containing amorphous carbon film.

### BACKGROUND ART

In portable display devices, such as a smartphone, a tablet terminal, and the like, a large number of functional layers are laminated over the surface of a glass substrate serving as a base of the display. Such functional layers are, for example, a hard coat layer for preventing scars and damage, an antireflection layer for reducing reflection of light, and an antifouling layer for preventing adhesion of smudges and fingerprints. For forming an antireflection film having a low refractive index, a coating liquid using a fluorine-containing alkoxysilane is proposed (see, for example, Patent Document 1). Also, an antireflection film having scratch resistance and an antifouling property and including a hard coating layer laminated on a low-refractive-index layer containing hollow inorganic nanoparticles is proposed (see, for example, Patent Document 2).

### RELATED ART DOCUMENTS

### Patent Documents

Patent Document 1: Japanese Laid-Open Patent Application Publication No. 2015-224302
Patent Document 2: Japanese Laid-Open Patent Application Publication No. 2021-76849

### SUMMARY OF THE INVENTION

### Problem to be Solved by the Invention

Since the conventional display devices are coated with a plurality of thin films having different functions, such as an antireflection layer and an antifouling layer, their production process is complicated and high in cost. When the low-refractive-index antireflection film proposed in Patent Document 1 is used, a hard coating layer and an antifouling layer are additionally necessary. The antireflection film proposed in Patent Document 2 is a composite film of a hard coating layer and a low-refractive-index layer, and its production method is complicated and high in cost.

In view of the above issues, it is an object of the present invention to provide a fluorine-containing amorphous carbon film having properties of hard coating, antireflection, and antifouling, and a method for producing the fluorine-containing amorphous carbon film.

### Means for Solving the Problem

In one aspect of the present invention, a fluorine-containing amorphous carbon film is a monolayer film formed of carbon, fluorine, and oxygen. An average fluorine content percentage in a film thickness direction is 30 atomic % or greater and 40 atomic % or less, an average oxygen content percentage in the film thickness direction is 5 atomic % or greater and 20 atomic % or less, and a remainder is a carbon atom.

In another aspect of the present invention, a method for producing a fluorine-containing amorphous carbon film includes: providing a substrate in a chamber; introducing, into the chamber, a raw material gas having a chemical formula represented only by carbon and fluorine, and an inert gas for diluting the raw material gas, and forming the fluorine-containing amorphous carbon film over a surface of the substrate while a plasma is generated; and setting a mixing ratio of the inert gas to the raw material gas to be greater than 1/4 and less than 11/1 in terms of a flow rate ratio into the chamber.

### Advantageous Effects of the Invention

A fluorine-containing amorphous carbon film having properties of hard coating, antireflection, and antifouling, and a method for producing the fluorine-containing amorphous carbon film are realized.

### BRIEF DESCRIPTION OF THE DRAWINGS

FIG. 1 is a schematic diagram of a fluorine-containing amorphous carbon film of an embodiment formed over a substrate.

FIG. 2 is a schematic diagram of a film forming apparatus used for producing the fluorine-containing amorphous carbon film.

FIG. 3 is a graph indicating a relationship between a gas flow rate ratio and a light transmittance in Example 1.

FIG. 4 is a graph indicating a relationship between the gas flow rate ratio and an extinction coefficient in Example 1.

FIG. 5 is a graph indicating a relationship between the gas flow rate ratio and a refractive index in Example 1.

FIG. 6 is a graph indicating a relationship between the gas flow rate ratio and a water droplet contact angle in Example 1.

FIG. 7 is a graph indicating a relationship between a film forming pressure and a light transmittance in Example 2.

FIG. 8 is a graph indicating element content percentages of films formed at different pressures in Example 2.

FIG. 9 is a graph indicating a relationship between a film forming pressure and a refractive index in Example 2.

FIG. 10 is a graph indicating a relationship between the film forming pressure and a water droplet contact angle in Example 2.

FIG. 11 is a table indicating element content percentages at varied gas flow rate ratios in Example 3.

FIG. 12 is a graph indicating a relationship between the gas flow rate ratio and a refractive index in Example 3.

FIG. 13 is a graph indicating a relationship between the gas flow rate ratio and a light transmittance in Example 3.

FIG. 14 is a graph indicating a relationship between the gas flow rate ratio and a water droplet contact angle in Example 3.

FIG. 15 is a graph indicating a relationship between the gas flow rate ratio and a film forming rate.

### EMBODIMENTS FOR CARRYING OUT THE INVENTION

In the following, a fluorine-containing amorphous carbon film of the present invention and a method for producing the fluorine-containing amorphous carbon film will be described in detail with reference to the drawings. The embodiments described below are illustrative for embodying the technical idea of the invention, and should not be construed as limiting the present invention to the following configurations and numerical values. In the drawings, members having the same function are denoted by the same reference sign, and duplicate description thereof may be omitted. Partial substitution or combination between different embodiments or configuration examples are possible. The size, positional relationship, and the like of the members as illustrated in each drawing may be exaggerated for ease of understanding of the invention.

### Configuration of Fluorine-Containing Amorphous Carbon Film

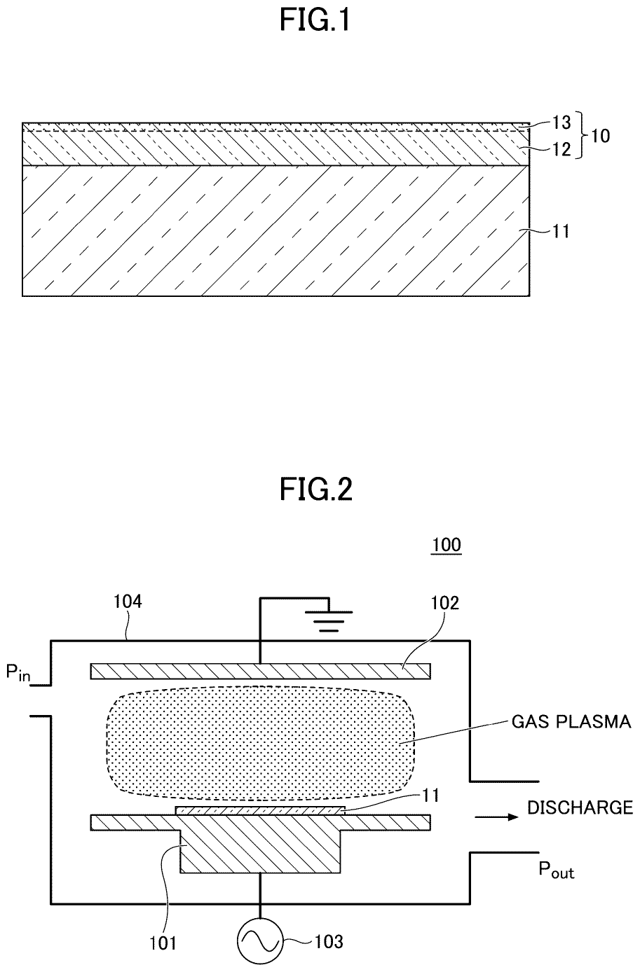

FIG. 1 is a schematic diagram of a fluorine-containing amorphous carbon film 10 of an embodiment formed over a surface of a substrate 11 serving as a base. The fluorine-containing amorphous carbon film 10 is a monolayer thin film formed in a single film forming step. A thickness of the fluorine-containing amorphous carbon film 10 can be appropriately designed in accordance with a member to which the fluorine-containing amorphous carbon film 10 is to be applied. For example, the thickness of the fluorine-containing amorphous carbon film 10 is 25 nm or greater and 500 nm or less, and preferably 50 nm or greater and 250 nm. The fluorine-containing amorphous carbon film 10 includes a surface region and a region 12 that is on the substrate 11 side, i.e., deeper than the surface region. The fluorine content percentage of the surface region is different from that of the region 12. A vicinity of the surface of the fluorine-containing amorphous carbon film 10, specifically a shallow region of less than 10 nm in depth from the surface, is a high-concentration fluorine-containing region 13 having a fluorine content percentage greater than that of the region 12 that is 10 nm or greater in depth.

The fluorine-containing amorphous carbon film 10 is a monolayer film formed of carbon, fluorine, and oxygen. In the embodiments and claims, the reference to the fluorine-containing amorphous carbon film 10 as a film “formed of carbon, fluorine, and oxygen” or a film “composed of carbon, fluorine, and oxygen” should be construed not to consider, as constituent elements, a trace amount of impurities that are unavoidably or unintentionally mixed.

An average fluorine content percentage of the fluorine-containing amorphous carbon film 10 in the film thickness direction is 30 atomic % or greater and 40 atomic % or less, an average oxygen content percentage of the fluorine-containing amorphous carbon film 10 in the film thickness direction is 5 atomic % or greater and 20 atomic % or less, and the remainder is the carbon atom. In the high-concentration fluorine-containing region 13, i. e., the surface region, the fluorine content percentage is 50 atomic % or greater and 75 atomic % or less, the oxygen content percentage is 5 atomic % or greater and 20 atomic % or less, and the remainder is the carbon atom. A composition of the region 12 that is 10 nm or greater in depth from the surface is as follows. Specifically, the fluorine content percentage is 30 atomic % or greater and 40 atomic % or less, the oxygen content percentage is 5 atomic % or greater and 20 atomic % or less, and the remainder is the carbon atom. Regarding the average content percentage of each element in the film thickness direction, the composition of the region 12, which is 10 nm or greater in depth from the surface, is dominant.

The fluorine-containing amorphous carbon film 10 is a very hard film having a low refractive index and excellent water repellency, and is a monolayer having the functions of hard coating, antireflection, and antifouling. The fluorine-containing amorphous carbon film 10 is applied to the surface of a glass base of a display, a transparent panel, or the like. The hard coating property refers to a property of suppressing scars and cracks in the glass base caused by application of an impact from the outside, and includes abrasion resistance and scratch resistance. A film referred to as a hard coating is required not only to enable prevention of scars and cracks but also to have a hardness sufficient to protect a base. The base is formed of a glass material, such as quartz glass, soda-lime glass, sapphire glass, optical glass, or the like. For protecting the base, preferably, the fluorine-containing amorphous carbon film 10 has a hardness of 0.65 GPa or greater as measured through nanoindentation. Use in a display terminal or a transparent panel also requires a high light transmittance. As described below, the light transmittance of the fluorine-containing amorphous carbon film 10 of the embodiment is 90%, preferably 95% or higher, and more preferably 98% or higher.

The antireflection property is the function of reducing reflection of light using optical interference. When the fluorine-containing amorphous carbon film 10 is applied to a display, the reflection of light on the display surface is reduced to enhance visibility. For this purpose, the fluorine-containing amorphous carbon film 10 is required to have a refractive index that is low relative to that of the underlying base. The highest refractive index of the fluorine-containing amorphous carbon film 10 is 1.40±0.02, which is lower than the refractive index of quartz glass (1.50). When the fluorine-containing amorphous carbon film 10 is formed under preferable conditions, the refractive index of the fluorine-containing amorphous carbon film 10 can be reduced to 1.32, and the resulting fluorine-containing amorphous carbon film 10 has a high antireflection function.

The antifouling property refers to a property that adhesion of smudges does not readily occur. Use in a display requires a low surface free energy or a large water contact angle (high water repellency) for preventing adhesion of smudges and fingerprints on the outermost surface of the display. The fluorine-containing amorphous carbon film 10 has a large water droplet contact angle of 95° or greater, i.e., high water repellency. A reason for this will be described below.

### Method for Producing Fluorine-Containing Amorphous Carbon Film

FIG. 2 is a schematic diagram of a film forming apparatus 100 used for producing the fluorine-containing amorphous carbon film 10. The fluorine-containing amorphous carbon film 10 is formed using a raw material gas having a chemical formula represented only by carbon (C) and fluorine (F), and an inert gas. That is, a gas mixture of a hydrogen atom-free fluorocarbon gas and an inert gas is used.

The film forming apparatus 100 is a CVD (chemical vapor deposition) film forming apparatus. The CVD is high in film forming rate and large in processing area, and can form a film having a density higher than that of a film formed through vacuum deposition. In this example, the film forming apparatus 100 is a capacitively coupled radio frequency plasma CVD apparatus, and includes a pair of parallel plate electrodes 101 and 102 in a chamber 104. The chamber 104 is configured such that the substrate 11 can be placed between the electrodes 101 and 102. For example, the substrate 11 can be placed on the lower electrode 101.

During film formation, the interior of the chamber 104 is maintained to be in a moderate or high vacuum of 24 Pa or less. One of the electrodes, i.e., the electrode 101, is connected to a radio frequency power supply 103, and the other electrode 102 is grounded. A plasma is generated by applying a radio frequency power between the electrodes 101 and 102. Frequencies used to excite a low-temperature plasma are the HF band (3 MHz to 30 MHz), the VHF band (30 MHz to 300 MHz), and the UHF band (300 MHz to 3,000 MHz). In the embodiment, a power supply frequency of 13.56 MHz, which is typically used in a plasma excitation process, is used. A raw material gas and an inert gas for diluting the raw material gas are introduced from a gas inlet port Pin into the chamber 104, and thus a gas plasma is generated in the chamber 104. Molecules of the raw material gas are decomposed by the plasma in the chamber 104, and chemical species generated by the decomposition are deposited on the substrate 11. An unnecessary gas is exhausted from an exhaust port Pout.

As the raw material gas, it is possible to use at least one gas selected from methane tetrafluoride (CF₄), ethane hexafluoride (C₂F₆), propane octafluoride (C₃F₈), and cyclobutane octafluoride (C₄F₈). The inert gas for dilution is argon (Ar), nitrogen (N), krypton (Kr), xenon (Xe), or the like. By using a hydrogen-atom-free fluorocarbon gas as the raw material gas, it is possible to eliminate CH bonds, which tend to increase the refractive index due to polarization.

The method for producing a fluorine-containing amorphous carbon film includes:
a) providing the substrate 11 in the chamber 104 of the film forming apparatus 100;
b) introducing, into the chamber 104, a raw material gas having a chemical formula represented only by carbon and fluorine, and an inert gas for diluting the raw material gas, and forming the fluorine-containing amorphous carbon film over a surface of the substrate 11 while a plasma is generated; and
c) setting a mixing ratio of the inert gas to the raw material gas to be greater than 1/4 and less than 11/1 in terms of a flow rate ratio into the chamber 104. More preferably, the flow rate ratio of the inert gas to the raw material gas into the chamber 104 is 1/2 or greater and 7/2 or less. A reason for this preferable range of the mixing ratio of the inert gas to the raw material gas will be described below.

### Evaluation of Properties

In the following, a plurality of types of samples are produced under varied film forming conditions of the fluorine-containing amorphous carbon film 10, and are evaluated for properties.

### Example 1

An SiO₂ substrate is used as the substrate 11. The SiO₂ substrate is placed on the electrode 101, and a low-temperature plasma is excited by applying a radio frequency power of 13.56 MHz and 200 W to the film forming apparatus 100. The internal pressure of the chamber 104 before plasma ignition is set to 24 Pa, and an Ar gas and a C₄F₈ gas are introduced into the chamber 104. A flow rate ratio (Ar/C₄F₈) of the introduced Ar gas to the introduced C₄F₈ gas is changed to 1/4, to 1/2, and to 1/1. A plasma is generated by application of a radio frequency power, thereby preparing three types of samples as films at each of the flow rate ratios such that the final film thickness is 50 nm, 100 nm, and 150 nm. The prepared samples are measured for film thickness, element content percentage, light transmittance, extinction coefficient, refractive index, water droplet contact angle, and hardness. The film thickness is determined through fitting of measurement data after creating a structural model of a thin film through spectroscopic ellipsometry used for measurement of the extinction coefficient and the refractive index, which will be described below.

### (1) Element Content Percentage

The element content percentage is measured using the samples each having a film thickness of 150 nm and prepared at the Ar/C₄F₈ flow rate ratio set to 1/4 and 1/1. The surface of the sample and the interior of the sample, which is the film, are measured for the element content percentage through X-ray photoelectron spectroscopy (XPS). Here, the interior of the film is formed through Ar etching at an acceleration energy of 700 kV. The measurement of the interior of the film is performed at 10 nm and 30 nm in depth from the surface. JPS-9010TR obtained from JEOL Ltd. is used as an apparatus for the XPS. The depth resolution of the surface of the film and the interior of the film is about 5 nm. The element percentages in the interior of the film were the same at depths of 10 nm and 30 nm, and thus are collectively treated as the element percentages in the interior of the film.

Specifically, the element percentages of the sample prepared at the Ar/C4F₈ flow rate ratio of 1/4 are as follows.
Element percentages of the surface of the film:
F content percentage: 50 atomic %;
C content percentage: 38 atomic %; and
O content percentage: 12 atomic %.
Element percentages of the interior of the film:
F content percentage: 32 atomic %;
C content percentage: 58 atomic %; and
O content percentage: 10 atomic %.

The element percentages of the sample prepared at the Ar/C₄F₈ flow rate ratio of 1/1 are as follows.
Element percentages of the surface of the film:
F content percentage: 73 atomic %;
C content percentage: 23 atomic %; and
O content percentage: 4 atomic %.
Element percentages of the interior of the film:
F content percentage: 38 atomic %;
C content percentage: 54 atomic %; and
O content percentage: 8 atomic %. By setting the Ar/C₄F₈ flow rate ratio to 1/1, the F content percentage of the surface of the film was increased to 73 atomic %. The F content percentage of the interior of the film also increases, although not as much as that of the surface of the film. This indicates that the Ar/C₄F₈ flow rate ratio influences an element profile in the film thickness direction of the fluorine-containing amorphous carbon film 10.

### (2) Light Transmittance

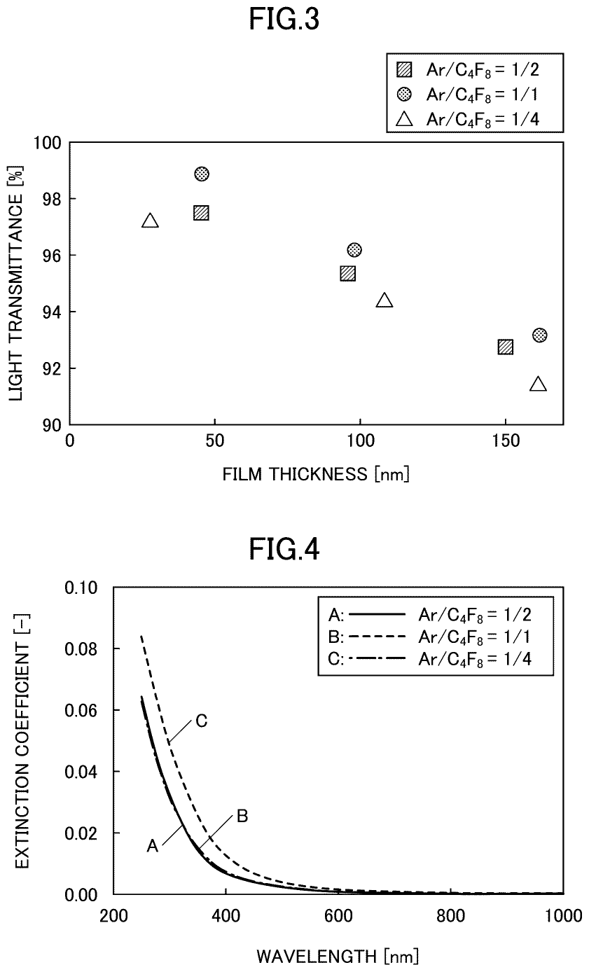

FIG. 3 indicates light transmittances of the samples prepared to have the different film thicknesses at the different gas flow rate ratios. The light transmittances of the samples prepared to have the film thicknesses of 50 nm, 100 nm, and 150 nm at the three varied gas flow rate ratios as described above are measured with an ultraviolet-visible spectrometer (UV-Vis 3600Plus, obtained from Shimadzu Corporation). Gray circles indicate the light transmittances of the samples prepared at the Ar/C₄F₈ flow rate ratio of 1/1. Gray squares indicate the light transmittances of the samples prepared at the Ar/C₄F₈ flow rate ratio of 1/2. White triangles indicate the light transmittances of the samples prepared at the Ar/C₄F₈ flow rate ratio of 1/4. Slight variation in the film thickness of some of the samples is due to variation in the process. Regardless of the gas flow rate ratios, high light transmittances are achieved in all the samples. Light transmittances exceeding 90% are still obtained when the film thickness is 150 nm. This suggests favorable applicability to a protective film for a display. When the film thickness is 100 nm or less, the light transmittances are 94% or higher. When the film thickness is 50 nm, the light transmittances are 97% or higher. The Ar/C₄F₈ flow rate ratio of 1/4 still provides the light transmittances that are high enough to be applicable to a display.

### (3) Extinction Coefficient

FIG. 4 indicates light absorption of the samples prepared at the different gas flow rate ratios. Sample A corresponds to a sample indicating the film thickness dependency of the transmittance by the gray squares in FIG. 3. Sample B corresponds to a sample indicating the film thickness dependency of the transmittance by the gray circles in FIG. 3. Sample C corresponds to a sample indicating the film thickness dependency of the transmittance by the white triangles in FIG. 3. The horizontal axis is a wavelength, and the vertical axis is an extinction coefficient. Similar to the refractive index described below, the extinction coefficient is measured through spectroscopic ellipsometry using an imaging ellipsometer EP4 obtained from Accurion GmbH. The extinction coefficient represents the extent of light absorption. In all the samples, the extinction coefficient at a wavelength of 350 nm is small, i.e., 0.025 or less, and there is substantially no absorption of visible light.

Especially, when the Ar/C₄F₈ flow rate ratio is 1/2, the extinction coefficient becomes 0.010 or less.

The Ar/C₄F₈ flow rate ratio of 1/4 still provides the extinction properties that are enough to be applicable to a display.

### (4) Refractive Index

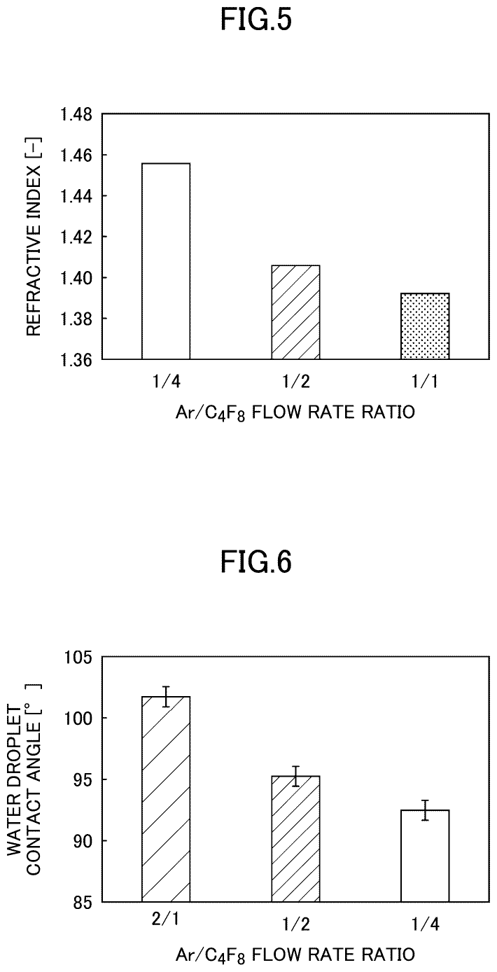

FIG. 5 indicates the refractive index at a wavelength of 550 nm of the samples prepared at the different gas flow rate ratios. The refractive index of the sample prepared at the Ar/C₄F₈ flow rate ratio of 1/2 is 1.40, and the refractive index of the sample prepared at the Ar/C₄F₈ flow rate ratio of 1/1 is 1.39. Whereas, the refractive index of the sample prepared at the Ar/C₄F₈ flow rate ratio of 1/4 is 1.46. The sample prepared at the Ar/C₄F₈ flow rate ratio of 1/4 is favorable in the light transmittance and the extinction coefficient, but cannot have a sufficiently reduced refractive index. Thus, this has difficulty being applied in a state in which an antireflection function is preferentially required.

### (5) Water Droplet Contact Angle

FIG. 6 indicates the water droplet contact angle of the samples prepared at the different gas flow rate ratios. The water droplet contact angle of each sample is measured by a drop method using DM-500 obtained from Kyowa Interface Science Co., Ltd. The water droplet contact angle of the sample prepared at the Ar/C₄F₈ flow rate ratio of 1/2 is 95°, and the water droplet contact angle of the sample prepared at the Ar/C₄F₈ flow rate ratio of 1/4 is 92.5°. Both the samples have sufficient water droplet contact angles, i.e., have high antifouling effects. As a reference, the water droplet contact angle of a sample prepared at a higher Ar ratio, i.e., an Ar/C₄F₈ flow rate ratio of 2/1, is 101.7°, and has high water repellency. From the viewpoint of antifouling, the Ar/C₄F₈ flow rate ratio is 1/4 or greater, and preferably 1/2 or greater.

### (6) Hardness

The hardness of each sample is measured through nanoindentation. In the measurement performed through nanoindentation, a film thickness of 250 nm or greater is preferable. Thus, samples having a film thickness of 250 nm are used to measure the hardness. The measurement is performed using Nano Indenter G200 obtained from Toyo Corporation. The hardness of the sample prepared at the Ar/C₄F₈ flow rate ratio of 1/2 is 0.76 GPa, and the hardness of the sample prepared at the Ar/C₄F₈ flow rate ratio of 1/1 is 0.65 GPa. The hardness of the sample prepared at the Ar/C₄F₈ flow rate ratio of 1/4 is 0.48 GPa, which is a hardness that is slightly insufficient compared to those of the other samples.

In view of the above-described evaluation of the properties in Example 1, for satisfying all requirements of hard coating, antireflection, and antifouling, the flow rate ratio of the raw material gas (fluorocarbon gas) to the inert gas is desirably greater than 1/4, and more desirably equal to or greater than 1/2.

### Example 2

In Example 2, a plurality of types of samples are prepared at a fixed Ar/C₄F₈ flow rate ratio and at varied film forming pressures. The film forming apparatus 100 using the radio frequency plasma CVD, which is the same as that used in Example 1, is used. Ar and C₄F₈ are used as the inert gas and the raw material gas, respectively. By applying a radio frequency power of 13.56 MHz and 200 W to the electrode 101 under reduced pressure, a plasma is excited between the electrode 101 and the electrode 102 facing the electrode 101, thereby forming the fluorine-containing amorphous carbon film 10 over the substrate 11 of quartz glass placed on the electrode 101. The Ar/C₄F₈ flow rate ratio is set to 1/2, and the film forming pressure is changed to 12 Pa, to 24 Pa, and to 48 Pa. The samples produced at the film forming pressures are measured for film thickness, light transmittance, element content percentage of the interior of a film, refractive index, and water droplet contact angle.

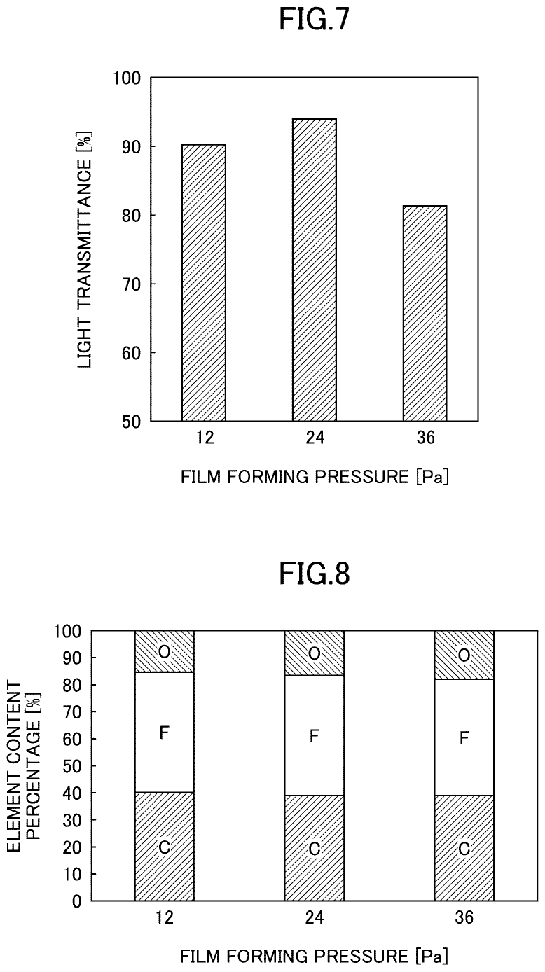

FIG. 7 indicates a relationship between the film forming pressure and the light transmittance. The film forming pressure is shown as the resultant pressure of the internal gas pressures of the chamber 104 during the film formation. When the film forming pressure is 12 Pa and 24 Pa, a light transmittance of 90% or higher is obtained, while when the film forming pressure is 36 Pa, the light transmittance decreases to be lower than 85%. Therefore, the film forming pressure is preferably set to be lower than 36 Pa, e.g., 35 Pa or lower, preferably 30 Pa or lower, and more preferably 24 Pa or lower.

FIG. 8 indicates element content percentages of films formed at different pressures. The element content percentages are measured at a depth of 20 nm from the film surface through etching and XPS. No significant difference is found in the carbon (C) content percentage. The fluorine (F) content percentage is 45 atomic % at the film forming pressures of 12 Pa and 24 Pa, while the fluorine (F) content percentage is 40 atomic & at the film forming pressure of 36 Pa and the oxygen (O) content percentage increases accordingly. For increasing the fluorine content percentage to lower the refractive index and ensure a hardness and transparency, the film forming pressure is desirably lower than 36 Pa, e.g., 35 Pa or lower, preferably 30 Pa or lower, and more preferably 24 Pa or lower.

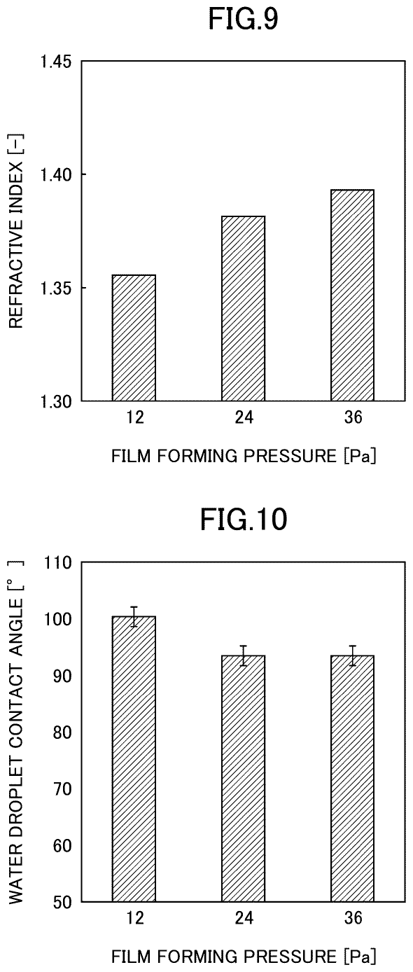

FIG. 9 indicates a relationship between the film forming pressure and the refractive index. When the film forming pressure is 24 Pa, a refractive index of 1.38 is obtained, and when the film forming pressure is 12 Pa, a refractive index of lower than 1.36 is realized. When the film forming pressure is 36 Pa, the refractive index is 1.40. The film having the refractive index of 1.40 can be still used as an antireflection film. However, considering a hardness and transparency, the film forming pressure is found to be preferably lower than 36 Pa, e.g., 35 Pa or lower, preferably 30 Pa or lower, and more preferably 24 Pa or lower.

FIG. 10 indicates a relationship between the film forming pressure and the water droplet contact angle. When the film forming pressure is 24 Pa and 36 Pa, a contact angle of approximately 95° is obtained, and when the film forming pressure is 12 Pa, a contact angle exceeding 100° is obtained.

The pressure of 36 Pa can still provide a fluorine-containing amorphous carbon film having an antifouling effect.

It is confirmed based on the results of Example 2 that, for providing the resulting film with all the functions of hard coating, antireflection, and antifouling, the film forming pressure is preferably lower than 36 Pa, e.g., 35 Pa or lower, preferably 30 Pa or lower, and more preferably 24 Pa or lower. However, the lower the film forming pressure, the lower the film forming rate (1 nm/s at the film forming pressure of 24 Pa, and 0.5 nm/s at the film forming pressure of 12 Pa). Thus, for realizing a film forming rate suitable for practical use at an industrial level, the film forming pressure is desirably 6 Pa or higher.

### Example 3

In Example 3, the film forming pressure is fixed and the ratio of the inert gas to the raw material gas is changed to be higher, thereby evaluating compositions and properties. The substrate 11 of quartz glass is provided in the film forming apparatus 100 that is the same as used in Examples 1 and 2, and the film forming pressure is fixed at 24 Pa. The inert gas is an Ar gas, and the raw material gas is a C₄F₈ gas. Samples each having a film thickness of 250 nm are prepared by changing the Ar/C₄F₈ flow rate ratio to 1/2, to 3/2, to 5/2, and to 7/2, and are measured for element content percentage, refractive index, light transmittance, and water droplet contact angle. Measurement methods are the same as in Examples 1 and 2.

### (1) Element Content Percentage

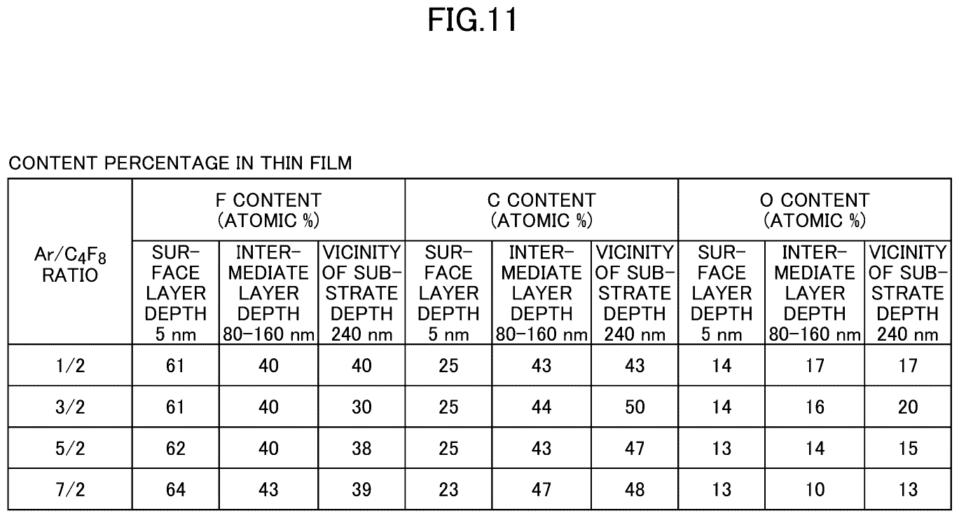

FIG. 11 indicates the element content percentages of the interior of each of the films prepared at varied gas flow rate ratios in Example 3. Etching is performed by accelerating Ar ions at 700 kV, and the element content percentage of the thin film is measured through XPS using JPS-9010TR obtained from JEOL Ltd. XPS measurement is performed at the following depths, i.e., a surface layer from the surface to 5 nm in depth, an intermediate layer 80 nm to 160 nm in depth, and the vicinity of the substrate 240 nm in depth. In the surface layer from the surface to 5 nm in depth, the fluorine (F) content percentage increases as the Ar/C₄F₈ flow rate ratio increases, and is higher than 61 atomic % in all the films. In the intermediate layer, the F content percentage is stable at 40 atomic % when the Ar/C₄F₈ flow rate ratio is 1/2, 3/2, and 5/2.

However, the F content percentage increases to 43 atomic % when the flow rate ratio is increased to 7/. In the vicinity of the substrate, the F content percentage is stable at approximately 40 atomic % except for the F content percentage at the flow rate ratio of 3/2, and is higher than 30 atomic & even at the flow rate ratio of 3/2. This result is consistent with the result of Example 1. The content percentage of the C element is higher in the intermediate layer and the vicinity of the substrate than in the surface layer. The content percentage of the 0 element in the film thickness direction does not significantly change, and is not so influenced by the change in the Ar/C₄F₈ flow rate ratio.

### (2) Refractive Index

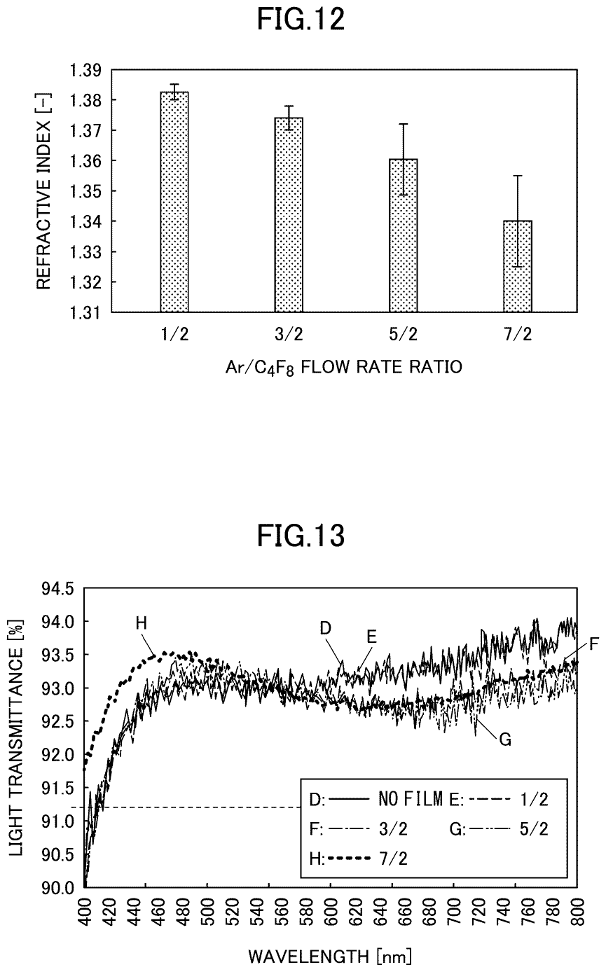

FIG. 12 indicates a relationship between the Ar/C₄F₈ flow rate ratio and the refractive index. Each of the samples prepared in Example 3 is measured through spectroscopic ellipsometry for the refractive index at a wavelength of 500 nm. The higher the Ar/C₄F₈ flow rate ratio, the lower the refractive index. At the flow rate ratio of 7/2, the refractive index is distributed in a range from 1.32 to 1.36, with a median being 1.34. It is expected that the refractive index of 1.32 can be stably obtained by reducing the film forming pressure and increasing the gas flow rate ratio. The fluorine-containing amorphous carbon film is effectively used as an antireflection film.

### (3) Light Transmittance

FIG. 13 indicates a relationship between the Ar/C₄F₈ flow rate ratio and the light transmittance. Each of the samples prepared in Example 3 is measured through ultraviolet-visible spectroscopy. As a reference, light having a wavelength of 400 nm to 800 nm is caused to transmit through the substrate 11 of quartz glass having no film on the surface, followed by measurement of a transmittance. “No film” in D is a transmission spectrum of the substrate 11 of quartz glass having no film on the surface. The Ar/C₄F₈ flow rate ratios of E, F, G, and H are 1/2, 3/2, 5/2, and 7/2, respectively. The transmittance of all the samples in the visible light region is 90% or higher, i.e., a high light transmittance.

### (4) Water Droplet Contact Angle

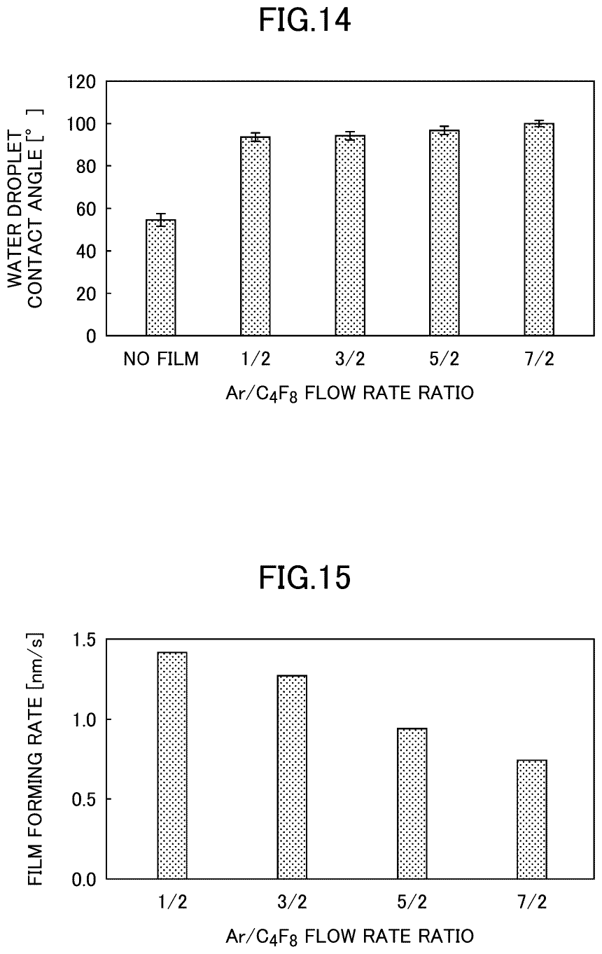

FIG. 14 indicates a relationship between the Ar/C₄F₈ flow rate ratio and the water droplet contact angle. Each of the samples prepared in Example 3 is measured by a drop method for the water droplet contact angle. As a reference, the water droplet contact angle of a quartz glass substrate having no film on the surface is measured. In all the samples, the water droplet contact angle is 90° or greater. The water droplet contact angle increases as the ratio of the Ar gas is increased. The water droplet contact angle is 94.6° when the flow rate ratio is 1/2, and the water droplet contact angle is 100.3° when the flow rate ratio is 7/2. The water droplet contact angle of the quartz glass substrate having no film on the surface does not reach 60°, indicating that the fluorine-containing amorphous carbon films of Example 3 have a high antifouling effect.

Based on the measurement and evaluation of Examples 1 to 3, the fluorine-containing amorphous carbon film 10 of the embodiment has the nature that the fluorine content percentage of the shallow region of less than 10 nm in depth from the surface is higher than that in the region 12 that is 10 nm or greater in depth. Abundant CF bonds in the surface layer suppress polarization, and an interaction induced by light or electromagnetic waves, such as reverse polarization or the like, is small. As a result, light is readily transmitted through the surface layer, and the refractive index of the surface layer is low. In the interior of the film, the fluorine content percentage is 40 atomic % on average. The polarization in the interior of the film is suppressed, and the refractive index of the interior of the film is very low. In this manner, in the fluorine-containing amorphous carbon film 10 of the embodiment, a fluorocarbon amorphous film having a high fluorine content percentage is formed in the vicinity of the surface, the fluorine content percentage is high in the interior of the film, and no hydrogen is contained. Thus, the fluorine-containing amorphous carbon film 10 is very excellent in optical characteristics.

Although C₄F₈ was used as the raw material gas in the above examples, another fluorocarbon gas, such as CF₄, C₂F₆, C₃F₈, or the like, may be used.

Alternatively, a gas mixture of two or more gases selected from CF₄, C₂F₆, C₃F₈, and C₄F₈ may be used. Decomposition of the fluorocarbon molecules is promoted by plasma excitation of an Ar gas, and formation of radicals and ions of C, F, and a CF group is promoted. Especially, when the flow rate of the Ar gas is 50% or higher relative to the flow rate of the fluorocarbon raw material gas, decomposition and activation of the fluorocarbon gas are promoted, and the fluorine content percentage of the interior of the film increases.

The fluorocarbon gas is dissociated by the Ar plasma to form an amorphous CF film. Also, the Ar ions have an etching effect. When the flow rate of the Ar gas is four times or greater that of the fluorocarbon raw material gas, the etching effect increases and the film forming rate decreases. FIG. 15 indicates a relationship between the gas flow rate ratio and the film forming rate at the film forming pressure of 24 Pa. The higher the Ar ratio, the lower the film forming rate. By extrapolating the bar graph in FIG. 15, it is possible to increase the flow rate ratio of the Ar gas until the film forming rate decreases up to 0.1 nm/s, which is considered unsuitable for practical use at an industrial level, and further improvement in optical characteristics can be expected. In this case, the flow rate ratio of the Ar gas to the raw material gas can be increased to 11/1. In view of the above, the flow rate ratio of the Ar gas to the raw material gas is preferably greater than 1/4 and equal to or less than 11/1.

At the moment when the plasma excitation is stopped, the etching effect due to the Ar ions is reduced. Thus, the activated CF radicals and CF ions are deposited in the vicinity of the surface to have a thickness of several nanometers, thereby forming an amorphous CF film having a high fluorine content percentage. As the fluorine content percentage of the surface increases, a surface reflectance decreases due to weak polarization of F atoms, and optical characteristics, such as an increase in light transmittance, a decrease in refractive index, and the like, are improved. Also, the surface free energy decreases to increase the water repellency, and thus the antifouling property is improved.

In conclusion, the fluorine-containing amorphous carbon film 10 of the embodiment is a monolayer film formed of carbon, fluorine, and oxygen, in which the fluorine content percentage is 30 atomic % or greater and 40 atomic % or less as the average value in the film thickness direction, the average oxygen content percentage in the film thickness direction is 5 atomic % or greater and 20 atomic % or less, and the remainder is the carbon atom. The shallow region of less than 10 nm in depth from the surface is the high-concentration fluorine-containing region 13, in which the fluorine content percentage is 50 atomic % or greater and 75 atomic % or less, the oxygen content percentage is 5 atomic or greater and 20 atomic % or less, and the remainder is the carbon atom.

The fluorine-containing amorphous carbon film 10 of the embodiment is a very hard film excellent in optical characteristics (low reflection, high light transmission, and low refractive index) and excellent in antifouling property, as a protective coating for a portable display, such as a smartphone or the like. Also, this film can be formed in a short time at a low cost using plasma CVD at a low pressure. The fluorine-containing amorphous carbon film 10 can be formed in a single film forming step, i.e., at a low cost, and is advantageous in terms of cost. A thin film excellent in optical characteristics and antifouling property can be inexpensively produced using a raw material gas having a chemical formula represented only by carbon and fluorine, and is suitable for mass production of the protective film for a display and a transparent panel.

The above disclosure includes the following embodiments.

### (Clause 1)

A fluorine-containing amorphous carbon film, wherein
the fluorine-containing amorphous carbon film is a monolayer film formed of carbon, fluorine, and oxygen, and
an average fluorine content percentage in a film thickness direction is 30 atomic % or greater and 40 atomic % or less, an average oxygen content percentage in the film thickness direction is 5 atomic % or greater and 20 atomic & or less, and a remainder is a carbon atom.

### (Clause 2)

The fluorine-containing amorphous carbon film according to clause 1, wherein
the fluorine-containing amorphous carbon film includes a high-concentration fluorine-containing region in a shallow region of less than 10 nm in depth from a surface, the high-concentration fluorine-containing region having a fluorine content percentage greater than a fluorine content percentage of a region that is 10 nm or greater in depth, and
   in the high-concentration fluorine-containing region, the fluorine content percentage is 50 atomic % or greater and 75 atomic % or less, an oxygen content percentage is 5 atomic % or greater and 20 atomic % or less, and a remainder is the carbon atom.

### (Clause 3)

The fluorine-containing amorphous carbon film according to clause 1 or 2, wherein
a refractive index of the monolayer film is 1.32 or higher and lower than 1.40.

### (Clause 4)

The fluorine-containing amorphous carbon film according to any one of clauses 1 to 3, wherein a light transmittance of the monolayer film is 90% or greater.

### (Clause 5)

The fluorine-containing amorphous carbon film according to any one of clauses 1 to 4, wherein
a water droplet contact angle of the monolayer film is 90° or greater.

### (Clause 6)

The fluorine-containing amorphous carbon film according to any one of clauses 1 to 5, wherein
a hardness of the monolayer film is 0.65 GPa or greater as measured through nanoindentation.

### (Clause 7)

The fluorine-containing amorphous carbon film according to any one of clauses 1 to 6, wherein
a thickness of the monolayer film is 25 nm or greater and 500 nm or less.

### (Clause 8)

The fluorine-containing amorphous carbon film according to clause 7, wherein
the thickness of the monolayer film is 50 nm or greater and 250 nm.

### (Clause 9)

A method for producing a fluorine-containing amorphous carbon film, the method including:
providing a substrate in a chamber;
introducing, into the chamber, a raw material gas having a chemical formula represented only by carbon and fluorine, and an inert gas for diluting the raw material gas, and forming the fluorine-containing amorphous carbon film over a surface of the substrate while a plasma is generated; and
setting a mixing ratio of the inert gas to the raw material gas to be greater than 1/4 and less than 11/1 in terms of a flow rate ratio into the chamber.

### (Clause 10)

The method for producing the fluorine-containing amorphous carbon film according to clause 9, wherein
the mixing ratio of the inert gas to the raw material gas is set to be 1/2 or greater and 7/2 or less in terms of the flow rate ratio into the chamber.

### (Clause 11)

The method for producing the fluorine-containing amorphous carbon film according to clause 9 or 10, wherein
an internal pressure of the chamber is set

### (Clause 12)

The method for producing the fluorine-containing amorphous carbon film according to clause 9 or 10, wherein
the raw material gas is CF₄, C₂F₆, C₃F₈, C₄F₈ , or a gas mixture of two or more selected therefrom.

### (Clause 13)

The method for producing the fluorine-containing amorphous carbon film according to any one of clauses 9 to 12, wherein
the inert gas is an Ar gas.

This application claims priority to Japanese Patent Application No. 2023-076611, filed on May 8, 2023, and incorporates the entire contents of this Japanese patent application herein by reference.

### REFERENCE SIGNS LIST

10 Fluorine-containing amorphous carbon film
11 Substrate
12 Region
13 High-concentration fluorine-containing region
100 Film forming apparatus
104 Chamber

1. A fluorine-containing amorphous carbon film, comprising:
a monolayer film formed of carbon, fluorine, and oxygen, wherein
an average fluorine content percentage of the monolayer film in a film thickness direction of the monolayer film is 30 atomic % or greater and 40 atomic % or less, an average oxygen content percentage of the monolayer film in the film thickness direction is 5 atomic % or greater and 20 atomic % or less, and a remainder of the monolayer film is a carbon.

2. The fluorine-containing amorphous carbon film according to claim 1, wherein
the fluorine-containing amorphous carbon film includes a high-concentration fluorine-containing region in a shallow region of less than 10 nm in depth from a surface of the monolayer film, the high-concentration fluorine-containing region having a fluorine content percentage greater than a fluorine content percentage of a region that is 10 nm or greater in depth, and
in the high-concentration fluorine-containing region, the fluorine content percentage is 50 atomic % or greater and 75 atomic % or less, an oxygen content percentage is 5 atomic % or greater and 20 atomic % or less, and a remainder is the carbon.

3. The fluorine-containing amorphous carbon film according to claim 1, wherein
a refractive index of the monolayer film is 1.32 or higher and lower than 1.40.

4. The fluorine-containing amorphous carbon film according to claim 1, wherein
a light transmittance of the monolayer film is 90% or greater.

5. The fluorine-containing amorphous carbon film according to claim 1, wherein
a water droplet contact angle of the monolayer film is 90° or greater.

6. The fluorine-containing amorphous carbon film according to claim 1, wherein
a hardness of the monolayer film is 0.65 GPa or greater as measured through nanoindentation.

7. The fluorine-containing amorphous carbon film according to claim 1, wherein
a thickness of the monolayer film is 25 nm or greater and 500 nm or less.

8. The fluorine-containing amorphous carbon film according to claim 7, wherein
the thickness of the monolayer film is 50 nm or greater and 250 nm or less.

9. A method for producing a fluorine-containing amorphous carbon film, the method comprising:
providing a substrate in a chamber;
introducing, into the chamber, a raw material gas of a molecule having a chemical formula represented only by carbon and fluorine, and an inert gas for diluting the raw material gas, and forming the fluorine-containing amorphous carbon film over a surface of the substrate while a plasma is generated; and
setting a mixing ratio of the inert gas to the raw material gas to be greater than 1/4 and less than 11/1 in terms of a flow rate ratio into the chamber.

10. The method for producing the fluorine-containing amorphous carbon film according to claim 9, wherein
the mixing ratio of the inert gas to the raw material gas is set to be 1/2 or greater and 7/2 or less in terms of the flow rate ratio into the chamber.

11. The method for producing the fluorine-containing amorphous carbon film according to claim 9, wherein
an internal pressure of the chamber is set to be 24 Pa or less.

12. The method for producing the fluorine-containing amorphous carbon film according to claim 9, wherein the raw material gas is CF₄, C₂F₆, C₃F₈, C₄F₈ , or a gas mixture of two or more selected from CF₄, C₂F₆, C₃F₈, and C₄F₈.

13. The method for producing the fluorine-containing amorphous carbon film according to claim 9, wherein
the inert gas is an Ar gas.
